(19) United States
(12) Patent Application Publication
(10) Pub. No.: US 2006/0220039 A1
(43) Pub. Date: Oct. 5, 2006

(54) Semiconductor device, method of manufacturing the same, and substrate for manufacturing the same

(75) Inventors: Mitsunori Yokoyama, Yamanashi (JP); Kenji Imanishi, Kawasaki (JP); Toshihide Kikkawa, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignees: EUDYNA DEVICES INC., Yamanashi (JP); FUJITSU LIMITED, Kawasaki (JP)

(21) Appl. No.: 11/391,288

(22) Filed: Mar. 29, 2006

(30) Foreign Application Priority Data
Mar. 31, 2005 (JP) 2005-101823

(51) Int. Cl. H01L 33/00

(52) U.S. Cl. 257/85

(57) ABSTRACT

A semiconductor device includes a substrate, a buffer layer that is formed with an aluminum nitride layer on the substrate and has a film thickness of 5 nm to 40 nm, an operating layer that is formed with a gallium nitride-based semiconductor on the buffer layer, and a control electrode that is formed on the operating layer.

### BACKGROUND OF THE INVENTION

1. Field of the Invention

The present invention generally relates to a semiconductor device, a method of manufacturing the semiconductor device, and a substrate to be used for manufacturing the semiconductor device, and more particularly, to a semiconductor device with a GaN-based semiconductor, a method of manufacturing the semiconductor device, and a substrate to be used for manufacturing the semiconductor device.

2. Description of the Related Art

Semiconductor devices with gallium nitride-based semiconductors (hereinafter referred to as GaN-based semiconductors), such as FETs (Field Effect Transistors) including HEMTs (High Electron Mobility Transistors), have been drawing attention as high-frequency high-power amplifier devices that operate on high power at high frequencies, such as amplifiers for cellular-phone base stations. A “GaN-based semiconductor” is a semiconductor that is formed with gallium nitride (GaN), aluminum nitride (AlN), or indium nitride (InN), or mixed crystals of those materials. For FETs with GaN-based semiconductors (hereinafter referred to as GaN-based FETs), techniques for achieving higher performances and higher reliabilities are being developed.

Japanese Unexamined Patent Publication No. 2002-57370 discloses a GaN-based semiconductor manufacturing method (hereinafter referred to as the prior art) by which a buffer layer made of aluminum nitride (hereinafter referred to as an AlN buffer layer) is grown on a substrate, and a GaN layer is grown on the AlN buffer layer. More specifically, an AlN buffer layer of 50 nm in film thickness is formed on a sapphire substrate by MOCVD (Metal Organic Chemical Vapor Deposition). Here, the film formation is carried out at a substrate temperature of 400 degrees centigrade, and NH₃ and TMA (trimethylaluminum) are used for a raw material gas. The substrate temperature is then increased to 1150 degrees centigrade, so as to form a GaN layer.

However, Japanese Unexamined Patent Publication No. 2002-57370 merely discloses a method of forming an AlN buffer layer. Therefore, the relationship between an AlN buffer layer and the performance and reliability of a GaN-based FET has not been made clear.

### SUMMARY OF THE INVENTION

It is therefore an object of the present invention to provide a semiconductor device, a method of manufacturing the semiconductor device, and a substrate to be used for manufacturing the semiconductor device in which the above disadvantage is eliminated.

A more specific object of the present invention is to provide a semiconductor device that makes clear the relationship between an AlN buffer layer and the performance and reliability of a GaN-based FET, and exhibits excellent performance and reliability, a method of manufacturing the semiconductor device, and a substrate to be used for manufacturing the semiconductor device.

According to one aspect of the present invention, preferably, there is provided a semiconductor device including: a substrate; a buffer layer that is formed with an aluminum nitride layer on the substrate and has a film thickness of 5 nm to 40 nm; an operating layer that is formed with a gallium nitride-based semiconductor on the buffer layer; and a control electrode that is formed on the operating layer. In accordance with the present invention, the film thickness of the buffer layer is 5 nm to 40 nm. Thus, a semiconductor device with excellent performance and reliability can be provided.

According to another aspect of the present invention, preferably, there is provided a method of manufacturing a semiconductor device, comprising forming a buffer layer on a substrate by metal organic chemical vapor deposition, the buffer layer being an aluminum nitride layer having a film thickness of 5 nm to 40 nm; forming an operating layer on the buffer layer by metal organic chemical vapor deposition, the operating layer being formed with a gallium nitride-based semiconductor; and forming a control electrode on the operating layer. In accordance with the present invention, the film thickness of the buffer layer is 5 nm to 40 nm. Thus, a method of manufacturing a semiconductor device with excellent performance and reliability can be provided.

According to another aspect of the present invention, preferably, there is provided a substrate used for fabricating a semiconductor device, including: a substrate; and a buffer layer that is formed with an aluminum nitride layer on the substrate and has a film thickness of 5 nm to 40 nm. In accordance with the present invention, the film thickness of the buffer layer is 5 nm to 40 nm. Thus, a substrate for semiconductor device manufacturing that enables the manufacturing of a semiconductor device with excellent performance and reliability can be provided.

In the above, the film thickness of the buffer layer may be 5 nm to 25 nm. In accordance with the present invention, a semiconductor device with even higher performance and higher reliability can be provided. The substrate may be one of a silicon carbide substrate, a sapphire substrate, and a gallium nitride-based semiconductor substrate. In accordance with the present invention, the crystallinity of the buffer layer and the operating layer can be improved. Thus, a semiconductor device with excellent performance and reliability can be provided. The operating layer may include a gallium nitride layer that is formed on the buffer layer and has a film thickness of 0.5 μm to 2.0 μm. In accordance with the present invention, the mobility of the 2D electron gas is increased. Thus, a semiconductor device with excellent performance can be provided.

In accordance with the present invention, the relationship between an AlN buffer layer and the performance and reliability of a GaN-based FET is made clear. Thus, a semiconductor device with excellent performance and reliability, a method of manufacturing such a semiconductor device, and a substrate to be used for manufacturing such a semiconductor device can be provided.

### BRIEF DESCRIPTION OF THE DRAWINGS

Other objects, features and advantages of the present invention will become more apparent from the following detailed description when read in conjunction with the accompanying drawings, in which:

FIG. 1 shows the pinch-off leakage current Ioff in relation to the AlN buffer layer;

FIG. 2 shows the current changing rate in relation to the AlN buffer layer;

FIG. 3 is a cross-sectional view of a substrate to be used for manufacturing a GaN-based FET in accordance with a first embodiment of the present invention; and

FIG. 4 is a cross-sectional view of the GaN-based FET in accordance with the first embodiment.

### DESCRIPTION OF THE PREFERRED EMBODIMENTS

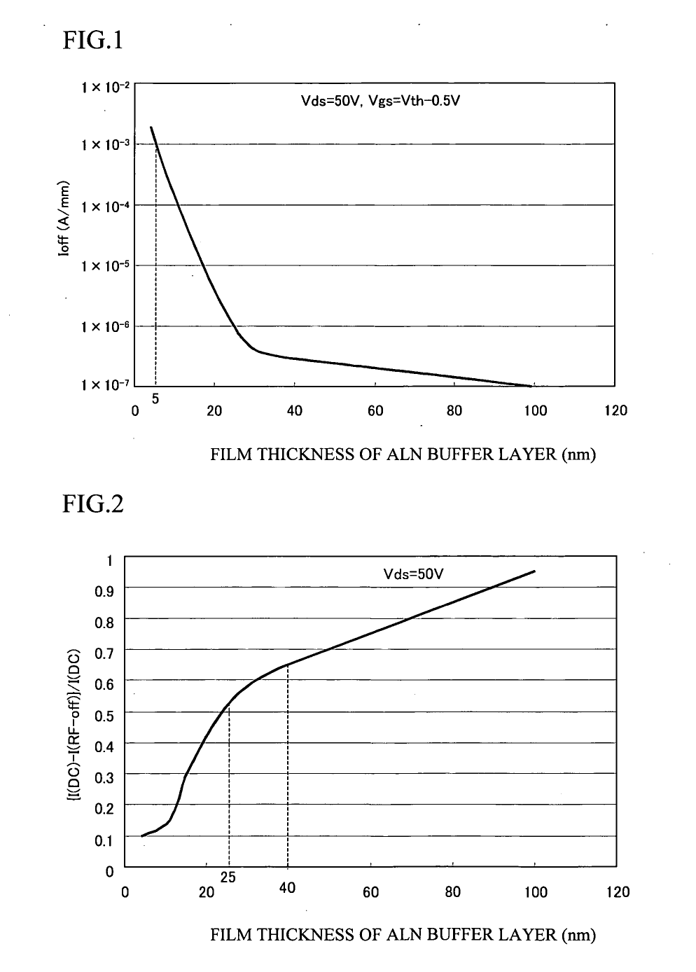

The inventors of the present invention have made clear the relationship between an AlN buffer layer and the performance and reliability of a GaN-based FET. In the following, the relationship is described. A GaN-based FET is produced, with the film thickness of the AlN buffer layer being varied in accordance with a method that will be later described as a first embodiment of the present invention. FIG. 1 shows the dependence of the pinch-off leakage current (Ioff) of the GaN-based FET on the film thickness of the AlN buffer layer. The “pinch-off leakage current (Ioff)” is a current to flow between a drain electrode and a source electrode when the FET is turned off. In FIG. 1, the drain current per unit gate width obtained when the drain voltage (Vds) is 50 V and the gate voltage (Vgs) is the FET threshold voltage (Vth) minus 0.5 V is set as Ioff.

A high pinch-off leakage current Ioff is not preferable for the GaN-based FET to achieve high performance. When the pinch-off leakage current Ioff exceeds 1×10⁻³ A/mm and the GaN-based FET operates on high power at a high frequency, the efficiency becomes lower and the distortion properties deteriorate. Such phenomena are not preferable for the GaN-based FET to operate as a high-frequency, high-power amplifier. As can be seen from FIG. 1, when the film thickness of the AlN buffer layer becomes smaller than 5 nm, the pinch-off leakage current Ioff becomes higher than 1×10⁻³ A/mm. This is because, as the film thickness of the AlN buffer layer becomes smaller, the resistance of the interface between the AlN buffer layer and the GaN layer on the buffer layer becomes lower.

FIG. 2 shows the dependence of the current changing rate on the film thickness of the AlN buffer layer at the time of high-frequency power cutoff where the film thickness of the AlN buffer layer of a GaN-based FET is varied. The “current changing rate” is the ratio of the difference between the drain current I(DC) prior to a high-frequency operation and the drain current I(RF-off) at the time of high-frequency power cutoff to the drain current I(DC), which is expressed as: [I(DC)−I(RF-off)]/I(DC). FIG. 2 shows the results of a case where the drain voltage (Vds) is 50 V.

A high current changing rate indicates that the drain current varies during a high-frequency, high-power operation. Therefore, a high current changing rate is not preferable for the GaN-based FET to achieve high reliability. Where the GaN-based FET is used as a high-frequency, high-power amplifier, for example, the current changing rate is preferably 0.7 or lower, and more preferably, 0.5 or lower. As can be seen from FIG. 2, when the film thickness of the AlN buffer layer becomes larger than 40 nm, the current changing rate becomes higher than 0.7. When the film thickness of the AlN buffer layer becomes larger than 25 nm, the current changing rate becomes higher than 0.5.

As described above, so as to achieve both a desired leakage current Ioff and a desired current changing rate in a GaN-based FET, or to achieve both high performance and high reliability with a GaN-based FET, the film thickness of the AlN buffer layer is preferably 5 nm to 40 nm, and more preferably, 5 to 25 nm. The following is a description of embodiments of the present invention, with reference to the accompanying drawings.

### First Embodiment

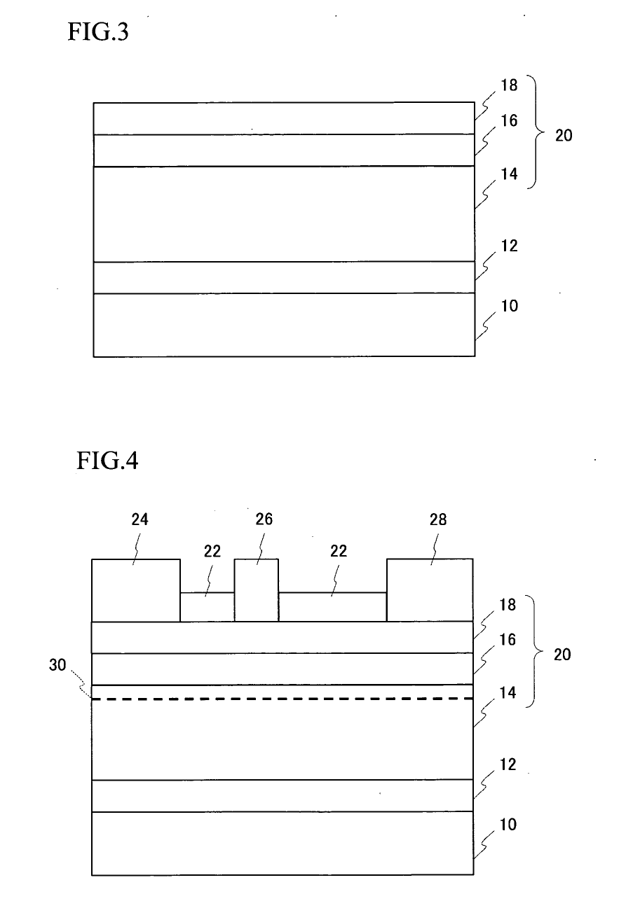

FIG. 3 is a cross-sectional view of a substrate to be used for manufacturing a GaN-based HEMT in accordance with a first embodiment of the present invention. This substrate used for fabricaging a semiconductor device is produced as follows. An AlN buffer layer 12 of 18 nm in film thickness is formed on a silicon carbonate (SiC) substrate 10 by MOCVD (Metal Organic Chemical Vapor Deposition) at a substrate temperature of 1300 degrees centigrade. The growth of the AlN buffer layer 12 is carried out where TMAl (trimethylaluminum) and NH₃ (ammonia) are used for the growth gas, the ratio of V to III is 10000, and the pressure is 6.7 kPa (50 torr). However, the AlN buffer layer 12 can be grown as long as the substrate temperature is in the range of 800 degrees centigrade to 1400 degrees centigrade, the V/III ratio is in the range of 1000 to 100000, and the pressure is in the range of 3.3 Pa to 101.3 kPa (25 torr to 760 torr).

Here, the substrate 10 may be a substrate that is formed with a GaN-based semiconductor as a nitride-based semiconductor, or a substrate that is made of sapphire, for example. With such a substrate, the AlN buffer layer 12 and a GaN-based semiconductor operating layer 20 with excellent crystallinity can be formed. Thus, a GaN-based FET with high performance and high reliability can be provided.

As the operating layer 20 formed with a GaN-based semiconductor, a GaN electron traveling layer 14, an AlGaN electron supply layer 16, and a GaN cap layer 18 are further formed in this order at a growth temperature of 1250 degrees centigrade. The GaN electron traveling layer 14 has a film thickness of 1.5 μm, with no impurities being added thereto. The AlGaN electron supply layer 16 has a film thickness of 30 nm, an n-type carrier concentration of 3×10¹⁸ cm⁻³, and an AlN mixed crystal ratio of 0.25, with Si being added thereto. The GaN cap layer 18 has a film thickness of 10 nm and an n-type carrier concentration of 5×10¹⁸ cm⁻³, with Si being added thereto.

The growth of the GaN electron traveling layer 14 is carried out where TMGa (trimethylgallium) and NH₃ are used for the growth gas, the V/III ratio is 5000, and the pressure is 13.3 kPa (100 torr). Instead of TMGa, TEGa (triethylgallium) may be used. In the case where TEGa is used, the pressure may be 6.7 kPa (50 torr), for example. Alternatively, the growth of the GaN electron traveling layer 14 may be carried out as long as the substrate temperature is in the range of 1000 degrees centigrade to 1400 degrees centigrade, the V/III ratio is in the range of 1000 to 100000, and the pressure is in the range of 3.3 kPa to 101.3 kPa (25 torr to 760 torr).

The growth of the AlGaN electron supply layer 16 is carried out where TMGa, TMAl, NH₃, and SiH₄ (silane) are used for the growth gas, the V/III ratio is 4000, and the pressure is 6.7 kPa (50 torr). Instead of TMGa, TEGa may be used. Alternatively, the growth of the AlGaN electron supply layer 16 may be carried out as long as the substrate temperature is in the range of 1000 degrees centigrade to 1400 degrees centigrade, the V/III ratio is in the range of 1000 to 100000, and the pressure is in the range of 3.3 kPa to 101.3 kPa (25 torr to 760 torr).

The growth of the GaN cap layer 18 is carried out where TMGa, NH₃, and SiH₄ are used for the growth gas, the V/III ratio is 2500, and the pressure is 13.3 kPa (100 torr). Instead of TMGa, TEGa may be used. Alternatively, the growth of the GaN cap layer 18 may be carried out as long as the substrate temperature is in the range of 1000 degrees centigrade to 1400 degrees centigrade, the V/III ratio is in the range of 1000 to 100000, and the pressure is in the range of 3.3 kPa to 101.3 kPa (25 torr to 760 torr). In this manner, the substrate for fabrication of a semiconductor device is completed.

Next, a GaN-based FET of the first embodiment is manufactured with the substrate used for fabricating a semiconductor device. FIG. 4 is a cross-sectional view of the GaN-based FET in accordance with the present invention. Using the above-described substrate for use in fabrication of semiconductor devices, a silicon nitride film 22 is formed on the GaN cap layer 18 or the operating layer 20 by CVD, for example. A gate electrode 26 (a control electrode) is then formed on the GaN cap layer 18 or the operating layer 20 through Ni/Au vapor deposition and liftoff, for example. A source electrode 24 and a drain electrode 28 are then formed on either side of the gate electrode 26 through Ti/Ai vapor deposition and liftoff, for example. In this manner, the GaN-based FET in accordance with the first embodiment is completed.

The GaN-based FET in accordance with the first embodiment includes the substrate 10, the AlN buffer layer (a buffer layer made of aluminum nitride) 12 that is formed on the substrate 10 and has a film thickness of 18 nm (which falls in the range of 5 nm to 40 nm), the GaN-based semiconductor operating layer (an operating layer formed with a gallium nitride semiconductor) 20 that is formed on the buffer layer 12, and the gate electrode (the control electrode) 26 that is formed on the operating layer 20. The operating layer 20 includes the electron traveling layer (a gallium nitride layer) 14 that is formed on the buffer layer 12 and has a film thickness of 1.5 μm (which falls in the range of 0.5 μm to 2.0 μm).

The electron traveling layer 14 has a two-dimensional (2D) electron gas formed in the vicinity of the interface with the electron supply layer 16, and functions as a channel layer to cause electrons to travel. The 2D electron gas has high electron mobility, so that the GaN-based FET in operation can exhibit high performance in terms of the yield, for example. If the film thickness of the electron traveling layer 14 is smaller than 0.5 μm, the mobility becomes low due to crystal deformation. If the film thickness of the electron traveling layer 14 is larger than 2.0 μm, cracks may be caused. Therefore, the film thickness of the electron traveling layer 14 is preferably 0.5 μm to 2.0 μm, and more preferably, 1.0 μm to 1.5 μm. Thus, a high-performance FET can be produced with high precision.

The electron supply layer 16 supplies electrons to the electron traveling layer 14, and functions to generate the 2D electron gas. The cap layer 18 functions to bring the source electrode 24 and the drain electrode 28 into ohmic contact with the operating layer 20. The cap layer 18 also serves to protect the electron supply layer. The silicon nitride film 22 serves to protect the operating layer 20, but an insulator other than silicon nitride may be employed in place of the silicon nitride film 22.

The source electrode 24 and the drain electrode 28 are in ohmic contact with the cap layer 18. The electrons that travel from the source electrode to the drain electrode 26 through the 2D electron gas are controlled by the gate electrode 26 so as to achieve the function of a FET.

In the GaN-based FET in accordance with the first embodiment, the film thickness of the AlN buffer layer 12 is made 18 nm, which falls in the range of 5 nm to 40 nm and in the more preferred range of 5 nm to 25 nm, so that the pinch-off leakage current Ioff can be 1×10³ A/mm, and the current changing rate can be 0.7 or lower, more preferably, 0.5 or lower. Thus, a high-performance GaN-based FET with high reliability can be provided.

The substrate for use in fabrication of the semiconductor device that is shown in FIG. 3 and is to be used for manufacturing the GaN-based FET of the first embodiment includes the substrate 10 and the AlN buffer layer (the buffer layer made of aluminum nitride) 12 that is formed on the substrate 10 and has a film thickness of 18 nm (which falls in the range of 5 nm to 40 nm). The substrate for semiconductor device manufacturing further includes the operating layer 20 that includes the electron traveling layer (the gallium nitride layer) 14 formed on the buffer layer 12 and having a film thickness of 1.5 μm (which falls in the range of 0.5 μm to 2.0 μm). Using this substrate for semiconductor device manufacturing, a high-performance GaN-based FET with high reliability can be manufactured.

Instead of the above described structure of the first embodiment, the operating layer 20 may have the structure of a GaN-based semiconductor layer, such as a semiconductor layer formed with a semiconductor made of GaN, AlN, or InN, or mixed crystals of them. In such a case, a high-performance GaN-based FET with high reliability can be provided, as in the first embodiment.

Although a few preferred embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A semiconductor device comprising:
a substrate;
a buffer layer that is formed with an aluminum nitride layer on the substrate and has a film thickness of 5 nm to 40 nm;
an operating layer that is formed with a gallium nitride-based semiconductor on the buffer layer; and
a control electrode that is formed on the operating layer.

2. The semiconductor device as claimed in claim 1, wherein the film thickness of the buffer layer is 5 nm to 25 nm.

3. The semiconductor device as claimed in claim 1, wherein the substrate is one of a silicon carbide substrate, a sapphire substrate, and a gallium nitride-based semiconductor substrate.

4. The semiconductor device as claimed in claim 1, wherein the operating layer includes a gallium nitride layer that is formed on the buffer layer and has a film thickness of 0.5 μm to 2.0 μm.

5. A method of manufacturing a semiconductor device, comprising the steps of:
forming a buffer layer on a substrate by metal organic chemical vapor deposition, the buffer layer being an aluminum nitride layer having a film thickness of 5 nm to 40 nm;
forming an operating layer on the buffer layer by metal organic chemical vapor deposition, the operating layer being formed with a gallium nitride-based semiconductor; and
forming a control electrode on the operating layer.

6. The method as claimed in claim 5, wherein the film thickness of the buffer layer is 5 nm to 25 nm.

7. The method as claimed in claim 5, wherein the substrate is one of a silicon carbide substrate, a sapphire substrate, and a gallium nitride-based semiconductor substrate.

8. The method as claimed in claim 5, wherein the operating layer includes a gallium nitride layer that is formed on the buffer layer and has a film thickness of 0.5 μm to 2.0 μm.

9. A substrate for semiconductor device comprising:
a substrate; and
a buffer layer that is formed with an aluminum nitride layer on the substrate and has a film thickness of 5 nm to 40 nm.

10. The substrate for semiconductor device as claimed in claim 9, wherein the film thickness of the buffer layer is 5 nm to 25 nm.

11. The substrate for semiconductor device as claimed in claim 9, wherein the substrate is one of a silicon carbide substrate, a sapphire substrate, and a gallium nitride-based semiconductor substrate.

12. The substrate for semiconductor device as claimed in claim 9, further comprising an operating layer that includes a gallium nitride layer that is formed on the buffer layer and has a film thickness of 0.5 μm to 2.0 μm.
